(19) United States
(12) Patent Application Publication
(10) Pub. No.: US 2006/0255337 A1
(43) Pub. Date: Nov. 16, 2006

(54) Multi-domain member for a display device

(75) Inventors: Sahng-Ik Jun, Seoul (KR); Dong-Gyu Kim, Yongin-si (KR)

Correspondence Address: DLA PIPER RUDNICK GRAY CARY US, LLP, 2000 UNIVERSITY AVENUE, E. PALO ALTO, CA, 94303-2248, US

(73) Assignee: Samsung Electronics Co., Ltd.

(21) Appl. No.: 11/413,685

(22) Filed: Apr. 28, 2006

(30) Foreign Application Priority Data
May 11, 2005 (KR) 10-2005-39389

(51) Int. Cl. H01L 29/04

(52) U.S. Cl. 257/59; 438/149

(57) ABSTRACT

A member for a display device includes a transparent substrate, a black matrix, a color filter and a transparent electrode. The transparent substrate includes a pixel region having a substantially V-shape and a light blocking region surrounding the pixel region. The black matrix is in the light blocking region. The color filter includes a plurality of color filter portions and a color filter overlapping portion. Each of the color filter portions is in the pixel region. The color filter overlapping portion is between adjacent color filter portions. The transparent electrode is on the color filter. The transparent electrode includes an opening that extends substantially parallel to a side of the pixel region. Therefore, an image display quality is improved.

### CROSS-REFERENCE TO RELATED APPLICATION

The present application claims priority from Korean Patent Application No. 2005-39389 filed on May 11, 2005, the disclosure of which is hereby incorporated herein by reference in its entirety.

### BACKGROUND OF THE INVENTION

1. Field of the Invention

The present invention relates to a display device member, a method of manufacturing the display device member, and a liquid crystal display (LCD) device having the member.

2. Description of the Related Art

An LCD device, in general, includes an array substrate having a thin film transistor (TFT), a color filter substrate, and a liquid crystal layer interposed between the array substrate and the color filter substrate. Liquid crystals of the liquid crystal layer change their orientation in response to an electric field applied thereto. The orientation of the liquid crystals affects light transmittance through the liquid crystal layer and controls the image that is displayed.

The liquid crystals have an optical anisotropy so that the image is displayed within a viewing angle. An LCD monitor for a desktop computer having a viewing angle of more than about 90° has been developed. The “viewing angle” is an angle between an imaginary line that is normal to a display surface and a line where the contrast ratio is about 10:1. The “contrast ratio” is the ratio of luminance level at a bright point and luminance level at a dark point in the display device. When the LCD device is capable of displaying a dark image and has a uniform luminance, the contrast ratio is increased.

The LCD device may include a normally black mode and a black matrix having a decreased reflectivity to prevent light leakage and to display darker images. When no voltage is applied to a common electrode and a pixel electrode of the LCD device operating in the normally black mode, a black image is displayed. In order to increase a luminance uniformity, the LCD device includes a compensation film or a multi-domain liquid crystal layer. The multi-domain liquid crystal layer has a plurality of domains, each domain capable of having a liquid crystal orientation that is different from the other domains.

In particular, when the liquid crystals of the liquid crystal layer are in a vertical alignment mode, the normally black mode and the multiple domains are easily formed.

In order to form the plurality of domains, the LCD device may include an in-plane switching (IPS) mode, a mixed vertical alignment (MVA) mode, a patterned vertical alignment (PVA) mode, etc.

When the LCD device operates in the MVA mode, a plurality of protrusions are formed on the color filter substrate and/or the thin film transistor (TFT) substrate to form the multiple domains, thereby increasing the viewing angle of the LCD apparatus. The protrusions are formed on the color filter substrate and/or the TFT substrate through additional process steps, such as a coating step, photo step, etc., thereby increasing the manufacturing cost of the LCD apparatus.

When the LCD apparatus operates in the PVA mode, a plurality of slits are formed in the common electrode to distort the electric field in the liquid crystal layer and form the multiple domains, thereby increasing the viewing angle of the LCD apparatus. However, the slits decrease the response speed of the liquid crystals.

When the LCD apparatus operates in the IPS mode, the TFT substrate includes a plurality of electrodes disposed substantially in parallel with one another to form the distorted electric field. The LCD apparatus operating in the IPS mode, however, has decreased luminance.

Hence, LCD apparatuses in each of MVA, PVA, and IPS mode has a disadvantage.

### SUMMARY OF THE INVENTION

The present invention provides a member for a display device capable of improving an image display quality.

The present invention provides a method of manufacturing the above-mentioned member.

The present invention provides a liquid crystal display (LCD) device having the above-mentioned member.

In one aspect, the invention is a display device member. The member includes a transparent substrate, a black matrix, a color filter and a transparent electrode. The transparent substrate includes a pixel region having a substantially V-shape and a light blocking region surrounding the pixel region. The black matrix is in the light blocking region. The color filter includes a plurality of color filter portions and a color filter overlapping portion. Each of the color filter portions is in the pixel region. The color filter overlapping portion is between adjacent color filter portions. The transparent electrode is on the color filter. The transparent electrode includes an opening that is patterned to extend substantially parallel to a side of the pixel region.

In another aspect, the invention is a method of manufacturing a display device. The method entails forming a black matrix in a light blocking region of a transparent substrate. The transparent substrate includes a pixel region having a substantially V-shape and the light blocking region surrounding the pixel region. The method further entails forming a plurality of color filter portions in the pixel region and forming a color filter overlapping portion in the light blocking region. A transparent conductive layer is deposited on the color filter portions and the color filter overlapping portion. The transparent conductive layer is partially etched to form an opening that extends substantially parallel to a side of the pixel region.

In yet another aspect, the invention is a liquid crystal display device that includes a first member, a second member and a liquid crystal layer. The first member includes an upper substrate, a black matrix, a color filter and a transparent electrode. The upper substrate includes a pixel region having a substantially V-shape and a light blocking region surrounding the pixel region. The black matrix is in the light blocking region. The color filter includes a plurality of color filter portions and a color filter overlapping portion. Each of the color filter portions is in the pixel region. The color filter overlapping portion is between adjacent color filter portions. The transparent electrode is on the color filter. The transparent electrode includes an opening that extends substantially parallel to a side of the pixel region. The second member includes a lower substrate, a switching element and a pixel electrode. The lower substrate is substantially parallel to the upper substrate. The switching element is on the lower substrate. The pixel electrode corresponds to the pixel region. The pixel electrode is electrically connected to an electrode of the switching element. The liquid crystal layer is interposed between the first and second members.

The opening pattern includes a pattern formed on the common electrode, a space between adjacent pixel electrodes, etc.

According to the present invention, a viewing angle and an opening ratio are increased to improve an image display quality. In addition, a manufacturing process is simplified to decrease a manufacturing cost.

### BRIEF DESCRIPTION OF THE DRAWINGS

The above and other advantages of the present invention will become more apparent by describing in detail exemplary embodiments thereof with reference to the accompanying drawings, in which:

FIG. 1 is a plan view showing a liquid crystal display (LCD) device in accordance with one embodiment of the present invention;

FIG. 2 is a plan view showing a second member shown in FIG. 1;

FIG. 3 is a plan view showing a first member shown in FIG. 1;

FIG. 4 is a plan view showing a pixel region and a light blocking region shown in FIG. 3;

FIG. 5 is a cross-sectional view taken along the line I-I′ shown in FIG. 1;

FIGS. 6, 8 and 10 are plan views showing a method of manufacturing the first member shown in FIG. 3;

FIG. 7 is a cross-sectional view taken along the line II-II′ shown in FIG. 6;

FIG. 9 is a cross-sectional view taken along the line III-III′ shown in FIG. 8;

FIG. 11 is a cross-sectional view taken along the line IV-IV′ shown in FIG. 10;

FIG. 12 is a plan view showing an LCD device in accordance with another embodiment of the present invention;

FIG. 13 is a cross-sectional view taken along the line V-V′ shown in FIG. 12;

FIG. 14 is a plan view showing an LCD device in accordance with another embodiment of the present invention;

FIG. 15 is a plan view showing an LCD device in accordance with another embodiment of the present invention;

FIG. 16 is a cross-sectional view taken along the line VI-VI′ shown in FIG. 15;

FIG. 17 is a cross-sectional view showing an LCD device in accordance with another embodiment of the present invention;

FIG. 18 is a cross-sectional view showing an LCD device in accordance with another embodiment of the present invention;

FIG. 19 is a cross-sectional view showing an LCD device in accordance with another embodiment of the present invention;

FIG. 20 is a graph showing a relationship between a pixel distance and a light transmittance of the LCD device shown in FIGS. 1 to 5;

FIG. 21 is a plan view showing a pixel electrode and an opening pattern corresponding to a point ‘a’ shown in FIG. 20; and

FIG. 22 is a plan view showing a pixel electrode and an opening pattern corresponding to a point ‘b’ shown in FIG. 20.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. Like numbers refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations, for example as a result of manufacturing techniques and/or tolerances, are to be expected. Thus, embodiments of the invention should not be construed as limited to the particular shapes of regions illustrated herein but are to include deviations in shapes. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A “member,” as used herein, refers to an object that is capable of being assembled with another member to form a device.

Hereinafter, the present invention will be described in detail with reference to the accompanying drawings.

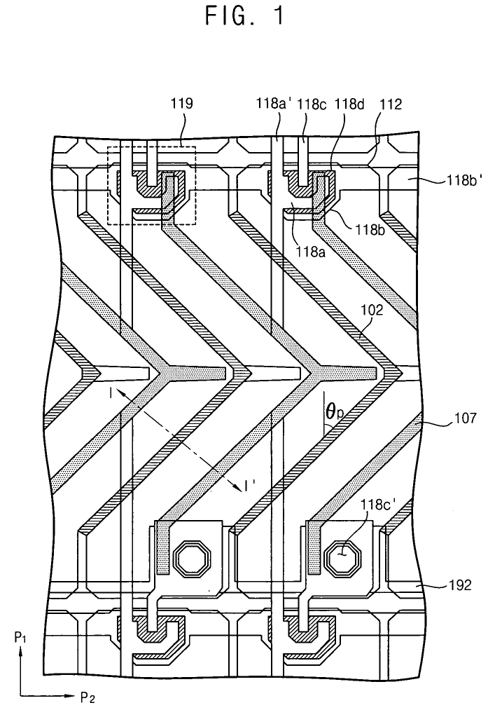

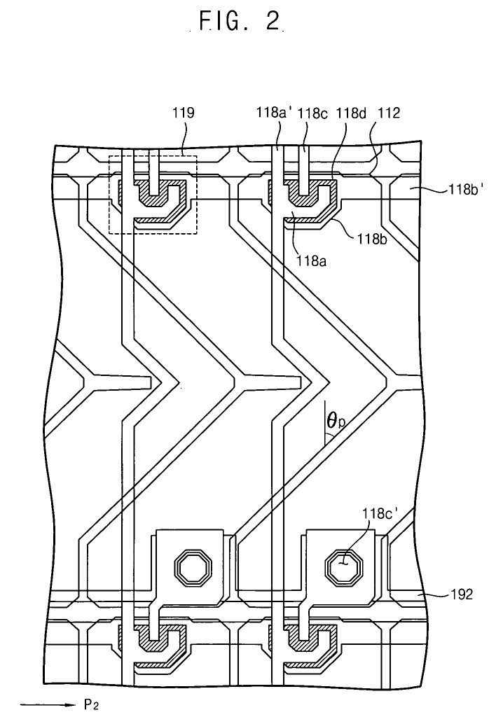

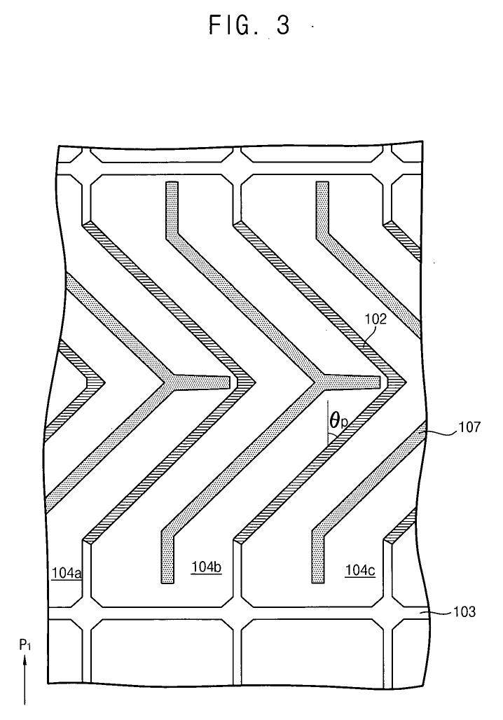

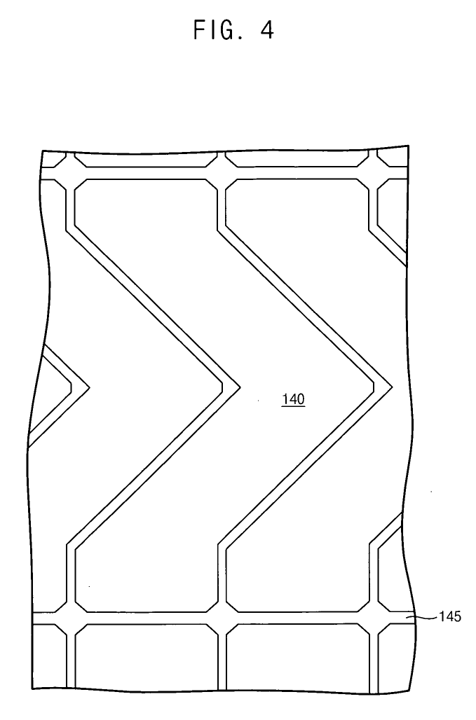

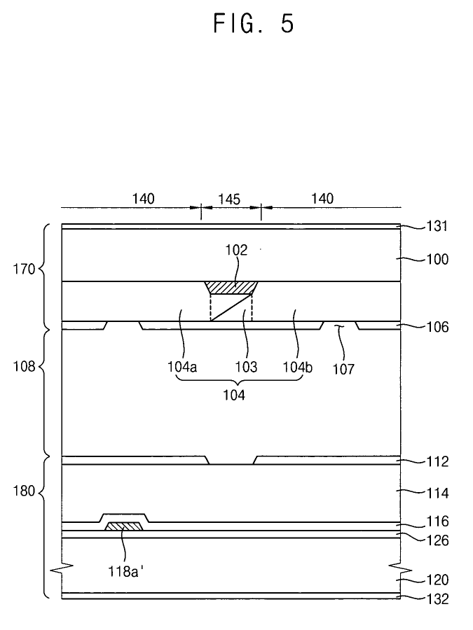

FIG. 1 is a plan view showing a liquid crystal display (LCD) device in accordance with one embodiment of the present invention. FIG. 2 is a plan view showing a second member shown in FIG. 1. FIG. 3 is a plan view showing a first member shown in FIG. 1. FIG. 4 is a plan view showing a pixel region and a light blocking region shown in FIG. 3. FIG. 5 is a cross-sectional view taken along the line I-I′ shown in FIG. 1.

Referring to FIGS. 1 to 5, the LCD device includes a first member 170, a second member 180 and a liquid crystal layer 108.

The first member 170 includes an upper polarizer 131, an upper substrate 100, a black matrix 102, a color filter 104, a common electrode 106 and a spacer (not shown). The first member 170 is divided into a plurality of pixel regions 140 and a light blocking region 145. An image is displayed in the pixel region 140, and light is blocked in the blocking region 145. Each of the pixel regions 140 may have a substantially V-shape, as shown in FIG. 4. The light blocking region 145 surrounds the pixel regions 140.

The second member 180 includes a lower polarizer 132, a lower substrate 120, a thin film transistor (TFT) 119, a data line 118a′, a gate line 118b′, a storage capacitor line 192, a gate insulating layer 126, a passivation layer 116, an organic layer 114 and a pixel electrode 112. In some embodiments, the second member 180 may further include a plurality of thin film transistors, a plurality of data lines, a plurality of gate lines, a plurality of storage capacitor lines and a plurality of pixel electrodes. The liquid crystal layer 108 is interposed between the first and second members 170 and 180.

The upper and lower substrates 100 and 120 may include a transparent glass, a transparent quartz, etc. Light may pass through the upper and lower substrates 100 and 120. The upper and lower substrates 100 and 120 preferably do not include alkaline ions. This is because when the upper and lower substrates 100 and 120 include alkaline ions, the alkaline ions may be dissolved in the liquid crystal layer 108 and decrease the resistivity of the liquid crystal layer 108, thereby compromising the image display quality and the adhesive strength between a sealant and the plates 100 and 120. In addition, the characteristics of the TFT 119 may also be deteriorated.

In some embodiments, the upper and lower substrates 100 and 120 may include a transparent high polymer. Examples of the transparent high polymer that can be used for the upper and lower substrates 100 and 120 include triacetylcellulose (TAC), polycarbonate (PC), polyethersulfone (PES), polyethyleneterephthalate (PET), polyethylenenaphthalate (PEN), polyvinylalcohol (PVA), polymethylmethacrylate (PMMA), cyclo-olefin polymer (COP), etc.

The upper and lower substrates 100 and 120 may be optically isotropic or anisotropic.

The upper polarizer 131 is on the upper substrate 100 to transmit light that is vibrating in a first polarizing direction P1. For example, the first polarizing direction P1 is substantially parallel to a predetermined direction in the LCD device. The lower polarizer 132 is on the lower substrate 120 to transmit light vibrating in a-second polarizing direction P2. The second polarizing direction P2 may be substantially perpendicular to the predetermined direction of the LCD device.

The black matrix 102 is disposed on a portion of the upper substrate 100 to block the light. The black matrix 102 blocks the light that would have passed through the light blocking region 145 to improve the image display quality. In FIGS. 1 to 5, the black matrix 102 has a substantially V-shape and fits between adjacent pixel electrodes 112. The black matrix 102 may be on a portion of the light blocking region 145. Alternatively, the black matrix 102 may be on an entire of the light blocking region 145. That is, the black matrix 102 is positioned between adjacent light blocking regions 145. Alternatively, the black matrix 102 may be positioned above the gate line 118b′.

An opaque organic material comprising photoresist is coated on the upper substrate 100 to form the black matrix 1.02 through a photo process. The opaque organic material includes carbon black, a pigment compound, a colorant compound, etc. The pigment compound may include a red pigment, a green pigment and a blue pigment, and the colorant compound may include a red colorant, a green colorant and a blue colorant. Alternatively, a metallic material may be deposited on the upper substrate 120 and partially etched to form the black matrix 102. The metallic material of the black matrix 102 may contains one or more of chrome (Cr), chrome oxide (CrOx), chrome nitride (CrNx), and other metals deemed suitable by a person skilled in the relevant art.

The color filter 104 is formed on the light blocking region 145 of the upper substrate 100 having the black matrix 102 to transmit the light having a predetermined wavelength. The color filter 104 contains one or more of a photo initiator, a monomer, a binder, a pigment, a dispersant, a solvent, and a photoresist. Other substances deemed suitable by a person skilled in the art may also be contained in the color filter 104.

The color filter 104 includes a red color filter portion 104a, a green color filter portion 104b, a blue color filter portion 104c and a color filter overlapping portion 103.

As shown in FIG. 3, each of the red, green and blue color filter portions 104a, 104b and 104c is in each of the pixel regions 140, and has a substantially V-shape in plan view. That is, the edges of the red, green and blue color filter portions 104a, 104b and 104c that extend diagonally with respect to the first polarizing direction P1 are substantially parallel to one other. Each of the red, green and blue color filter portions 104a, 104b and 104c is angled so that the V points to the right with respect to FIGS. 1-4. The left side of each of the red, green and blue color filter portions 104a, 104b and 104c is parallel to the right side of each of the red, green and blue color filter portions 104a, 104b and 104c. Each of the left and right sides is inclined with respect to the first polarizing direction P1 at a predetermined angle θp. The angle θp may be about 45°. Usually, the angle θp is determined by the first and second polarizing directions P1 and P2. When a difference between the first and second polarizing directions P1 and P2 is about 90°, the angle θp is about 45°.

At least two layers that are formed from the same material as the red, green and blue color filter portions 104a, 140b and 104c are overlapped to form the color filter overlapping portion 103. The color filter overlapping portion 103 is between adjacent color filter portions. For example, the color filter overlapping portion 103 is on the black matrix 102 to prevent the leakage of the light.

The common electrode 106 is formed on the upper substrate 100 having the black matrix 102 and the color filter 104. The common electrode 106 includes a transparent conductive material such as indium tin oxide (ITO), indium zinc oxide (IZO), zinc oxide (ZO), etc.

The common electrode 106 has an opening 107 in each of the pixel regions 140. There is an opening 107 in each of the pixel regions 140. The opening 107 may have a substantially Y-shape. Alternatively, the opening 107 may have a substantially V-shape. In addition, the common electrode 106 may further include a plurality of openings 107-that are substantially parallel to each other.

The spacer (not shown) is formed on the upper substrate 100 having the black matrix 102, the color filter 104 and the common electrode 106. The first member 170 is spaced apart from the second member 180 at a constant thickness by the spacer 110. For example, the spacer 110 is disposed at a position corresponding to the black matrix 102 and includes a column shape. Alternatively, the spacer 110 may include a ball-shaped spacer or a mixture of the column-shaped spacer and the ball-shaped spacer.

The gate line 118b′ is on the lower'substrate 120. In FIGS. 1 to 5, the gate line 118b′ is extends in the second polarizing direction P2, and corresponds to the light blocking region 145. The gate line 118b′ may also block the light from passing between the adjacent pixel electrodes 112, thus preventing light leakage.

The TFT 119 is on the lower substrate 120, and includes a source electrode 118a, a gate electrode 118b, a drain electrode 118c and a semiconductor layer pattern 118d. The source electrode 118a is electrically connected to the data line 118a′, and the gate electrode 118b is electrically connected to the gate line 118b′. The drain electrode 118c is electrically connected to the pixel electrode 112 through a contact hole 118c′. The contact hole 118c′ is in the organic layer 114 and the passivation layer 116. The semiconductor layer pattern 118d is between the source electrode 118a and the drain electrode 118c, and electrically insulated from the gate electrode 118b by the gate insulating layer 126. A driving integrated circuit (not shown) supplies the source electrode 118a with a data voltage through the data line 118a′, and supplies the gate electrode 118b with a gate signal through the gate line 118b′.

The gate insulating layer 126 is formed on the lower substrate 120 having the gate line 118b′, the storage capacitor line 192 and the gate electrode 118b so that the gate line 118b′, the storage capacitor line 192 and the gate electrode 118b is electrically insulated from the data line 118a′, the source electrode 118a, the drain electrode 118c and the semiconductor layer pattern 118d. The gate insulating layer 126 may include silicon oxide (SiOx), silicon nitride (SiNx), etc.

The data line 118a′ is on the gate insulating layer 118b′. In FIGS. 1 to 5, the data line 118a′ extends in the first polarizing direction P1, and a portion of the data line 118a′ extends at an angle to the first polarizing direction P1 along the pixel regions 140 to form a substantially V-shape. The data line 118a′ may extend diagonally with respect to the polarizing directions P1 and P2, along the sides of the pixel regions 140. Alternatively, the data line 118a′ may extend in the first polarizing direction P1.

The storage capacitor line 192 is on the gate insulating layer 126. The storage capacitor line 192 partially overlaps the pixel electrode 112. The storage capacitor line 192, a portion of the pixel electrode 112 overlapping the storage capacitor line 192, and the passivation and organic layers overlapping the storage capacitor line 192 form a storage capacitor. The storage capacitor maintains the voltage difference between the common electrode 106 and the pixel electrode 112 for one frame. In some embodiments, the storage capacitor line 192 may be omitted, and the pixel electrode 112 may partially overlap the previous gate line to form the storage capacitor.

The passivation layer 116 is disposed over the lower substrate 120 having the TFT 119, the data line 118a′ and the storage capacitor line 192. The passivation layer 126 may include the silicon oxide (SiOx), the silicon nitride (SiNx), etc.

The organic layer 114 is disposed on the lower substrate 120 having the TFT 119 and the passivation layer 116 so that the TFT 119 is electrically insulated from the pixel electrode 112. The organic layer 114 planarizes the lower substrate 120. The organic layer 114 adjusts the thickness of the liquid crystal layer 108.

The passivation and organic layers 116 and 114 include the contact hole 118c′ through which the drain electrode 1 18c is partially exposed.

The pixel electrode 112 is formed on the organic layer 114 in the pixel region 140 and in the contact hole 118c′ to be electrically connected to the drain electrode 118c. When the voltages are applied to the common electrode 106 and the pixel electrode 112, the liquid crystals of the liquid crystal layer 108 change their orientation in response to the electric field that forms through the liquid crystal layer 108. This change in the liquid crystal orientation affects the light transmittance through the liquid crystal layer 108. The pixel electrode 112 has a substantially V-shape in the pixel region 140 and each of the red, green and blue color filter portions 104a, 104b and 104c. The pixel electrode 112 and the opening 107 of the common electrode are arranged in a staggered manner, so that an opening between pixel electrodes 112 is not aligned with the opening 107 between the common electrodes 106. Alternatively, the pixel electrode 112 may have an auxiliary opening pattern (not shown) corresponding to the opening 107 of the common electrode 106. In addition, when the common electrode 106 has a plurality of openings 107, the pixel electrode 112 may have a plurality of auxiliary opening patterns (not shown). For example, each of left and right sides of the pixel electrode 112 may form an angle of about 45° with respect to the first polarizing direction P1. When the pixel electrode 112 has a substantially V-shape, the liquid crystal layer 108 has a uniform response speed so that the response speed of liquid crystals in a corner of each of the pixel regions 140 is substantially the same as that of liquid crystals in a central portion of each of the pixel regions 140.

The pixel electrode 112 includes a transparent conductive material. Examples of the transparent conductive material that can be used for the transparent electrode include indium tin oxide (ITO), indium zinc oxide (IZO), zinc oxide (ZO), etc. Alternatively, the pixel electrode 112 may include a high reflective material. In addition, each of the pixel regions may include a transmission portion and a reflection portion, and the pixel electrode 112 may include a transmission electrode in the transmission portion and a reflection electrode in the reflection portion.

The liquid crystal layer 108 is interposed between the first and second members 170 and 180, and sealed by a sealant (not shown). The liquid crystal layer 108 may include a vertical alignment (VA) mode.

When voltages are applied to the pixel electrode 112 and the common electrode 106, the electric field formed between the pixel electrode 112 and the common electrode 106 is distorted by the substantially V-shaped pixel electrode 112 and the opening 107 of the common electrode 106. The orientation of the liquid crystals of the liquid crystal layer 108 is changed by the distorted electric field, thus forming a plurality of domains in the liquid crystal layer 108. The plurality of domains increase the viewing angle.

According to the LCD device shown in FIGS. 1 to 5, the pixel electrode 112 has the substantially V-shape to increase the response speed of the liquid crystals of the liquid crystal layer 108. In addition, the color filter overlapping portion 103 and the black matrix 102 block the light between adjacent pixel electrodes to prevent light leakage. Therefore, a width of the black matrix 102 is decreased to increase the opening ratio.

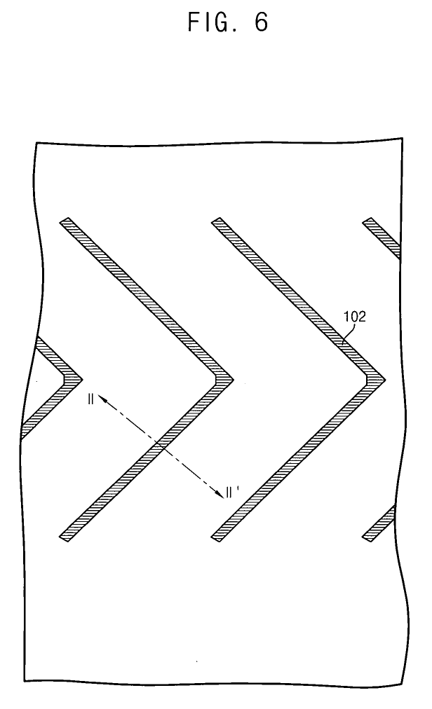

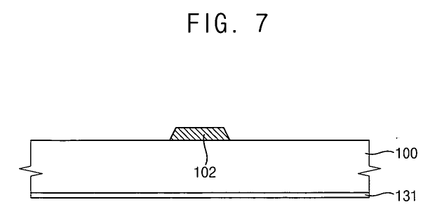

FIGS. 6, 8 and 10 are plan views showing a method of manufacturing the first member shown in FIG. 3. FIG. 6 is a plan view showing the formation of the black matrix 102. FIG. 7 is a cross-sectional view taken along the line 11-II′ shown in FIG. 6.

Referring to FIGS. 6 and 7, the upper polarizer 131 is formed on the upper substrate 100. For example, the upper polarizer 131 may be attached to the upper substrate 100 through an adhesive layer (not shown). A photoresist layer having an opaque material is coated on the upper substrate 100. The photoresist layer having the opaque material is exposed through a mask having a plurality of substantially V-shaped reticles. The exposed photoresist layer having the opaque material is developed to form the black matrix 102 having the substantially V-shape.

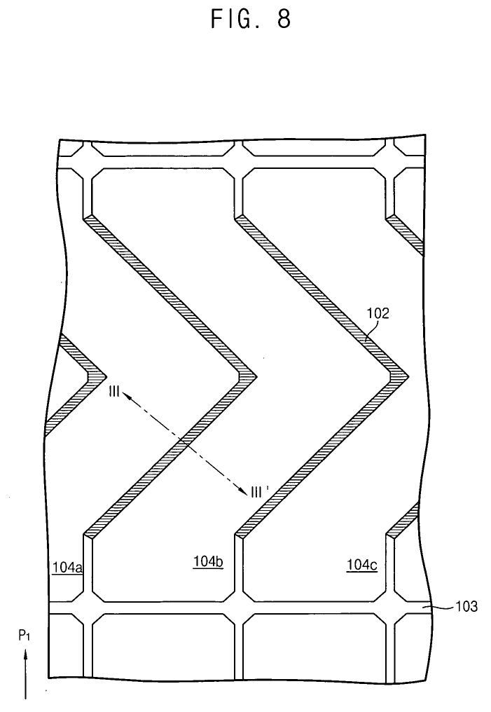

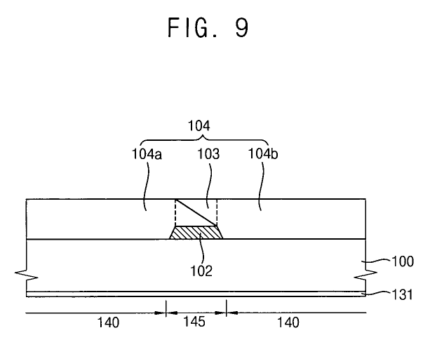

FIG. 8 is a plan view showing the formation of a color filter on the first member shown in FIG. 6. FIG. 9 is a cross-sectional view taken along the line III-III′ shown in FIG. 8.

Referring to FIGS. 8 and 9, a material for a red color filter portion is coated on the upper substrate 100 having the black matrix 102. The coated material for the red color filter portion is exposed through a mask (not shown). The exposed material for the red color filter portion is developed to form the red color filter portion 104a and a portion of the color filter overlapping portion 103. For example, the mask (not shown) for forming the red color filter portion 104a includes a transparent portion, a translucent portion and an opaque portion. The opaque portion of the mask (not shown) for forming the red color filter portion 104a corresponds to a red pixel region of the pixel regions 140. The translucent portion of the mask (not shown) for forming the red color filter portion 104a corresponds to the color filter overlapping portion 103 between adjacent pixel regions 140. Alternatively, the translucent portion of the mask (not shown) for forming the red color filter portion 104a may correspond to the light blocking region 145. The opaque portion of the mask (not shown) for forming the red color filter portion 104a corresponds to the green and blue color filter portions 104b and 104c.

The green and blue color filter portions 104b and 104c and the color filter overlapping portion 103 are formed through a substantially same method as the method for forming the red color filter portion 104a. The color filter overlapping portion 103 includes at least two of the materials for forming the red, green and blue color filter portions 104a, 104b and 104c. The color filter overlapping portion 103 blocks a portion of the light in the light blocking region 145 so that the width of the black matrix 102 may be decreased. When the color filter overlapping portion 103 blocks the portion of the light in the light blocking region 140, leakage of the light is prevented although the width of the black matrix 102 is decreased. In FIGS. 6 and 7, the color filter overlapping portion 103 includes two of the materials for forming the red, green and blue color filter portions 104a, 104b and 104c. A portion of the color filter overlapping portion 103 has a substantially V-shape that is similar to that of the black matrix 102.

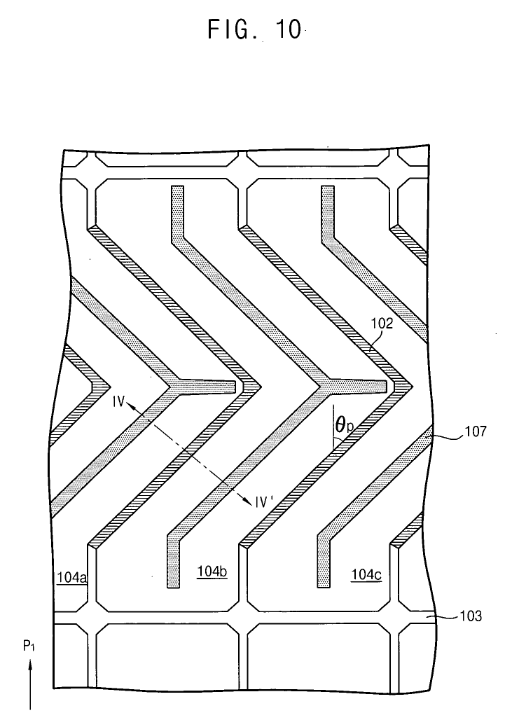

FIG. 10 is a plan view showing the formation of a common electrode on the first member shown in FIG. 8. FIG. 11 is a cross-sectional view taken along the line IV-IV′ shown in FIG. 10.

A transparent conductive material layer is deposited on the upper substrate 100 having the color filter 104 and the black matrix 102. A photoresist layer is coated on the transparent conductive material layer. The photoresist layer is exposed through a mask (not shown), and developed to form a photoresist pattern. The transparent conductive material layer is partially etched using the photoresist pattern as an etching mask to form the common electrode 106 having the opening 107.

Therefore, the first member 170 having the upper substrate 100, the black matrix 102, the color filter 104 and the common electrode 106 is completed.

Referring again to FIG. 5, the lower polarizer 132 is formed on the lower substrate 120. For example, the lower polarizer 132 is integrated with the lower substrate 120 through an adhesive layer (not shown).

A conductive material layer is deposited on a surface of the lower substrate 120 opposite to the lower polarizer 132. The conductive material layer is partially etched to form the gate electrode 118b, the gate line 118b′ and the storage capacitor line 192.

The gate insulating layer 126 is deposited on the lower substrate 120 having the gate electrode 118b, the gate line 118b′, and the storage capacitor line 192.

An amorphous silicon layer (not shown) is deposited on the gate insulating layer 126. N+ type impurities are implanted into an upper portion of the amorphous silicon layer (not shown) to form an N+ amorphous silicon layer (not shown). The amorphous silicon layer (not shown) and the N+ amorphous silicon layer (not shown) are partially etched to form the semiconductor layer pattern 118d.

A conductive material layer (not shown) is deposited on the gate insulating layer 126 having the semiconductor layer pattern 118d. The conductive material layer (not shown) is partially etched to form the source electrode 118a, the data line 118a′ and the drain electrode 118c. A portion of the data line 118a′ has a substantially V-shape.

A transparent insulating material layer (not shown) is deposited on the gate insulating layer 126 having the semiconductor layer pattern 118d, the source electrode 118a, the data line 118a′ and the drain electrode 118c.

An organic material layer (not shown) is coated on the transparent insulating material layer (not shown). The transparent insulating material layer (not shown) and the organic material layer (not shown) are partially removed to form the contact hole 118c′ through which the drain electrode 118c is partially exposed, thereby forming the passivation layer 116 and the organic layer 114.

A transparent conductive material layer (not shown) is deposited on the organic layer 114 having the contact hole 118c′. The transparent conductive material layer (not shown) is partially etched to form the pixel electrode 112.

Therefore, the second member 180 having the lower substrate 120, the lower polarizer 132, the TFT 119, the data line 118a′, the gate line 118b′, the storage capacitor line 192, the gate insulating layer 126, the passivation layer 116, the organic layer 114 and the pixel electrode 112 is completed.

The liquid crystals are injected into a space between the first and second members 170 and 180. The injected liquid crystals are sealed by the sealant (not shown) to form the liquid crystal layer 108. Alternatively, the liquid crystals may be dropped on the first member 170 or the second member 180 having the sealant (not shown) so that the first member 170 is combined with the second member 180 to form the liquid crystal layer 108.

According to the LCD device shown in FIGS. 1 to 11, the pixel electrode 112 and the opening 107 of the common electrode 106 have a substantially V-shape to increase the response speed of the liquid crystals and the viewing angle. In addition, the black matrix 102 and the color filter overlapping portion 103 prevent the leakage of the light between the adjacent pixel regions 140 so that the width of the black matrix 102 may be decreased to increase the opening ratio of each of the pixel regions 140. Furthermore, an overcoating layer (not shown) of the first member 170 may be omitted so that the manufacturing process of the first member 170 may be simplified.

FIG. 12 is a plan view showing an LCD device in accordance with another embodiment of the present invention. FIG. 13 is a cross-sectional view taken along the line V-V′ shown in FIG. 12. The LCD device of FIGS. 12 and 13 is same as that of FIGS. 1 to 5 except for a storage capacitor extension part. Thus, the same reference numerals will be used to refer to the same or like parts as those described in FIGS. 1 to 5 and any further explanation concerning the above elements will be omitted.

Referring to FIGS. 12 and 13, the LCD device includes the first member 170, the second member 180 and the liquid crystal layer 108.

The first member 170 includes the upper polarizer 131, the upper substrate 100, the black matrix 102, the color filter 104, the common electrode 106 and a spacer (not shown). The first member.170 is divided into a plurality of pixel regions 140 and the light blocking region 145. Each of the pixel regions 140 may have a substantially V-shape. The light blocking region 145 surrounds the pixel regions 140.

The second member 180 includes the lower polarizer 132, the lower substrate 120, the thin film transistor (TFT) 119, the data line 118a′, the gate line 118b′, the storage capacitor line 192, the storage capacitor extension part 192a, the gate insulating layer 126, the passivation layer 116, the organic layer 114 and the pixel electrode 112. Alternatively, the second member 180 may further include a plurality of thin film transistors, a plurality of data lines, a plurality of gate lines, a plurality of storage capacitor lines, a plurality of storage capacitor extension parts and a plurality of pixel electrodes. The liquid crystal layer 108 is interposed between the first and second members 170 and 180.

The storage capacitor line 192 is on the gate insulating layer 126. The storage capacitor line 192 partially overlaps the pixel electrode 112. The storage capacitor line 192, a portion of the pixel electrode 112 overlapping the storage capacitor line 192, and the passivation and organic layers 116 and 114 overlapping the storage capacitor line 192 form a storage capacitor. The storage capacitor maintains a voltage difference between the common electrode 106 and the pixel electrode 112 for one frame.

The storage capacitor extension part 192a is covered by the gate insulating layer 126. The storage capacitor extension part 192a is electrically connected to the storage capacitor line 192. The storage capacitor extension part 192a may be between adjacent pixel electrodes 112. An electric power having a substantially same level is applied to the storage capacitor extension part 192a and the common electrode 106 so that there is no voltage difference between the storage capacitor extension part 192a and the common electrode 106. When a voltage difference is formed between the adjacent pixel electrodes 112, a fringe field is formed between the adjacent pixel electrodes 112 so that a portion of the liquid crystals are distorted by the fringe field. However, in FIGS. 12 and 13, the voltage of the storage capacitor extension part 192a is substantially the same as that of the common electrode 106. Thus, the fringe field between the adjacent pixel electrodes 112 is decreased. The width W2 of the storage capacitor extension part 192a may be greater than the width W1 of each of the adjacent pixel electrodes 112. Alternatively, the width W2 of the storage capacitor extension part 192a may be substantially equal to the width W1 of each of the adjacent pixel electrodes 112.

According to the LCD device shown in FIGS. 12 and 13, the storage capacitor extension part 192a functions as a shielding common electrode to decrease the fringe field between the adjacent pixel electrodes 112. In addition, the storage capacitor extension part 192a blocks a portion of the light between the adjacent pixel electrodes 112 to improve an image display quality.

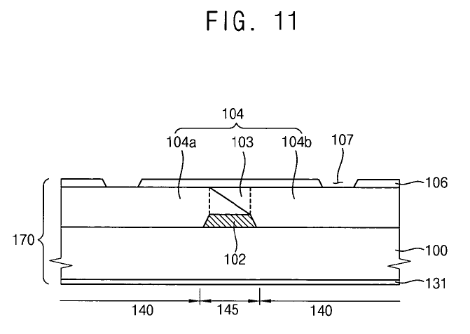

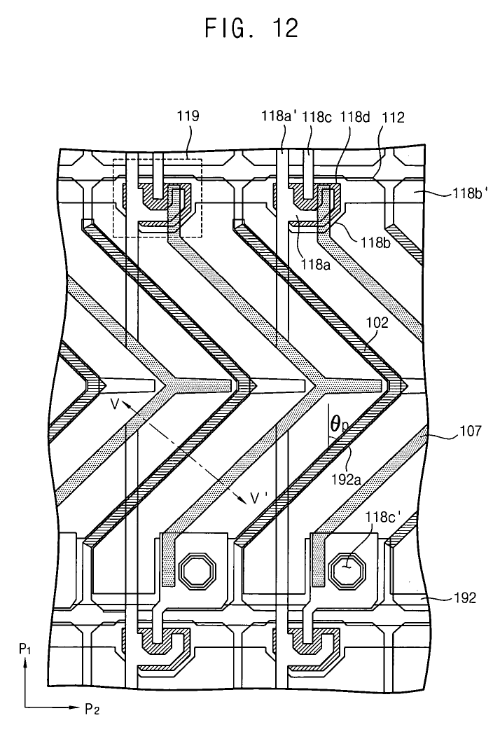

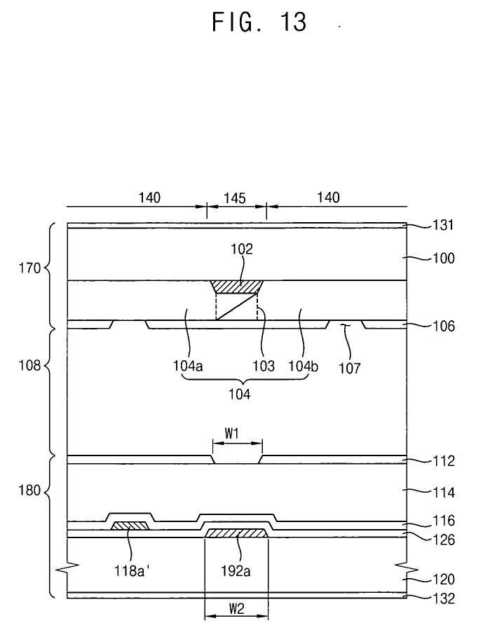

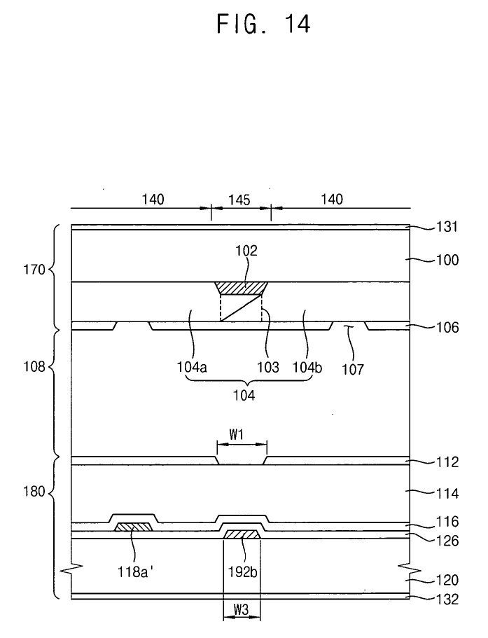

FIG. 14 is a plan view showing an LCD device in accordance with another embodiment of the present invention. The LCD device of FIG. 14 is the same as the device in FIGS. 12 and 13 except for a storage capacitor extension part. Thus, the same reference numerals will be used to refer to the same or like parts as those described in FIGS. 12 and 13 and any redundant explanation concerning these parts will be omitted.

Referring to FIG. 14, a storage capacitor line 192 is on a gate insulating layer 126. The storage capacitor line 192 partially overlaps a pixel electrode 112. The storage capacitor line 192, a portion of the pixel electrode 112 overlapping the storage capacitor line 192, and the passivation and organic layers 116 and 114 overlapping the storage capacitor line 192 form a storage capacitor.

The storage capacitor extension part 192b is covered by the gate insulating layer 126. The storage capacitor extension part 192b is electrically connected to the storage capacitor line 192. The storage capacitor extension part 192b may be between adjacent pixel electrodes 112. Voltage of substantially same level is applied to the storage capacitor extension part 192b and the common electrode 106 so that there is no voltage difference between the storage capacitor extension part 192b and the common electrode 106. The voltage of the storage capacitor extension part 192b is substantially the same as that of the common electrode 106. Thus, the fringe field between the adjacent pixel electrodes 112 is decreased. The width W3 of the storage capacitor extension part 192b is smaller than the width W1 of each of the adjacent pixel electrodes 112.

According to the LCD device shown in FIG. 14, the storage capacitor extension part 192b functions as a shielding common electrode to decrease the fringe field between the adjacent pixel electrodes 112. In addition, the width W3 of the storage capacitor extension part 192b is decreased to improve an opening ratio of the pixel regions 140.

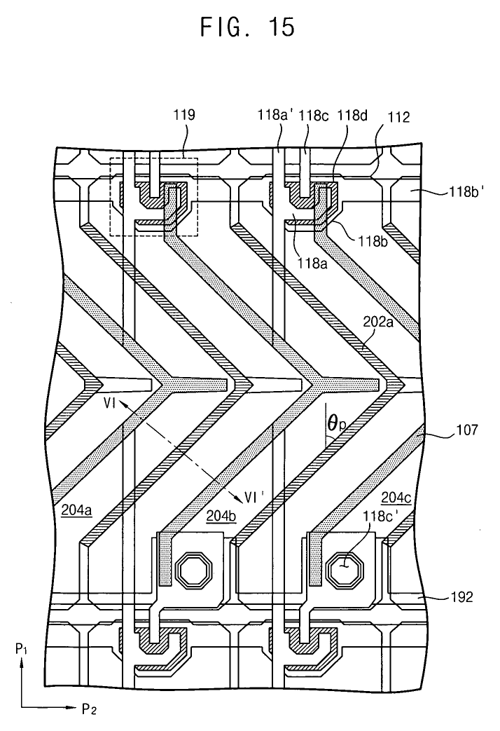

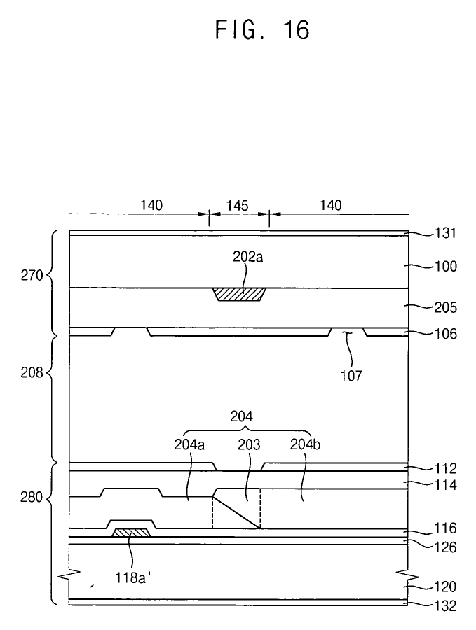

FIG. 15 is a plan view showing an LCD device in accordance with another embodiment of the present invention. FIG. 16 is a cross-sectional view taken along the line VI-VI′ shown in FIG. 15. The LCD device of FIGS. 15 and 16 is the same as that in FIGS. 1 to 5 except for a color filter and an overcoating layer. Thus, the same reference numerals will be used to refer to the same or like parts as those described in FIGS. 1 to 5 and any redundant explanation concerning these parts will be omitted.

Referring to FIGS. 15 and 16, the LCD device includes a first member 270, a second member 280 and a liquid crystal layer 108.

The first member 270 includes the upper polarizer 131, the upper substrate 100, a black matrix 202a, an overcoating layer 205, the common electrode 106 and a spacer (not shown). The first member 270 is divided into a plurality of pixel regions 140 and a light blocking region 145. Each of the pixel regions 140 may have a substantially V-shape. The light blocking region 145 surrounds the pixel regions 140.

The second member 280 includes the lower polarizer 132, the lower substrate 120, the thin film transistor (TFT) 119, the data line 118a′, the gate line 118b′, the storage capacitor line 192, the gate insulating layer 126, the passivation layer 116, a color filter 204, the organic layer 114 and the pixel electrode 112. Alternatively, the second member 180 may further include a plurality of thin film transistors, a plurality of data lines, a plurality of gate lines, a plurality of storage capacitor lines and a plurality of pixel electrodes. The liquid crystal layer 108 is interposed between the first and second members 270 and 280.

The black matrix 102 is disposed a portion of the upper substrate 100 to block light.

The overcoating layer 205 is on the upper substrate 100 having the black matrix 202a to planarize a surface of the upper substrate 100 having the black matrix 202a. In some embodiments, the overcoating layer 205 may be omitted.

The common electrode 106 is formed on the overcoating layer 205. The common electrode 106 has an opening 107 in each of the pixel regions 140.

The gate line 118b′ and the TFT 119 are on the lower substrate 120.

The gate insulating layer 126 is formed on the lower substrate 120 having the gate line 118b′, the storage capacitor line 192 and a gate electrode 118b so that the gate line 118b′, the storage capacitor line 192 and the gate electrode 118b is electrically insulated from the data line 118a′, a source electrode 118a, a drain electrode 118c and a semiconductor layer pattern 118d.

The data line 118a′ is on the gate insulating layer 118b′. The storage capacitor line 192 is on the gate insulating layer 126.

The passivation layer 116 is on the lower substrate 120 having the TFT 119, the data line 118a′ and the storage capacitor line 192.

The color filter 204 is on the passivation layer 116 to transmit the light having a predetermined wavelength.

The color filter 204 includes a red color filter portion 204a, a green color filter portion 204b, a blue color filter portion 204c and a color filter overlapping portion 203.

Each of the red, green and blue color filter portions 204a, 204b and 204c is in each of the pixel regions 140, and has a substantially V-shape.

At least two layers that are formed from the same layer as the red, green and blue color filter portions 204a, 204b and 204c are overlapped to form the color filter overlapping portion 203. The color filter overlapping portion 203 is between adjacent color filter portions. For example, the color filter overlapping portion 203 corresponds to the black matrix 202a to prevent leakage of the light in the light blocking region 145.

The organic layer 114 is disposed on the lower substrate 120 having the TFT 119, the passivation layer 116 and the color filter 204 so that the TFT 119 is electrically insulated from the pixel electrode 112. The organic layer 114 planarizes the lower substrate 120. The organic layer 114 adjusts the thickness of the liquid crystal layer 208.

The passivation and organic layers 116 and 114 and the color filter 204 include a contact hole 118c′ through which the drain electrode 118c is partially exposed.

The pixel electrode 112 is formed on the organic layer 114 in the pixel region 140 and in the contact hole 118c′ to be electrically connected to the drain electrode 118c.

The liquid crystal layer 208 is interposed between the first and second members 270 and 280, and sealed by a sealant (not shown).

According to the LCD device shown in FIGS. 15 and 16, the second member 280 includes the color filter 204 so that an image display quality of the LCD device is improved even if the first member 270 is misaligned with respect to the second member 280.

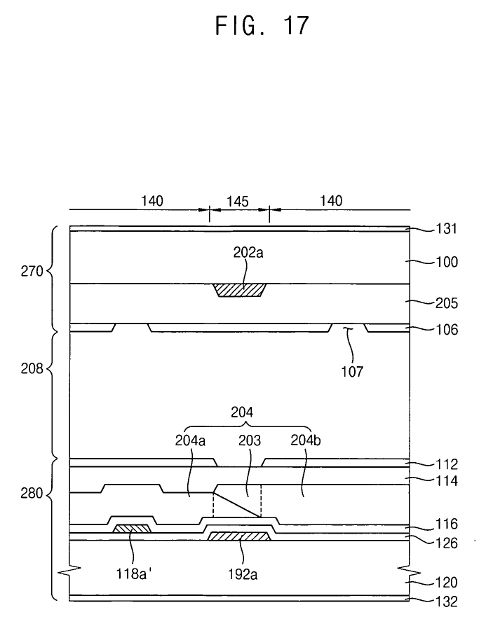

FIG. 17 is a cross-sectional view showing an LCD device in accordance with another embodiment of the present invention. The LCD device of FIG. 17 is the same as the device in FIGS. 15 and 16 except for a storage capacitor extension part. Thus, the same reference numerals will be used to refer to the same or like parts as those described in FIGS. 15 and 16, and any redundant explanation concerning these parts will be omitted.

Referring to FIG. 17, a storage capacitor line 192 is on the lower substrate 120, and covered with a gate insulating layer 126.

The storage capacitor extension part 192a is covered by the gate insulating layer 126. The storage capacitor extension part 192a is electrically connected to the storage capacitor line 192. The storage capacitor extension part 192a may be between adjacent pixel electrodes 112.

According to the LCD device shown in FIG. 17, the storage capacitor extension part 192a functions as a shielding common electrode to decrease the fringe field between the adjacent pixel electrodes 112. In addition, the storage capacitor extension part 192a blocks a portion of the light between the adjacent pixel electrodes 112 to improve an image display quality. Furthermore, the second member 280 includes the color filter 204 so that an image display quality of the LCD device is improved even if the first member 270 is misaligned with respect to the second member 280.

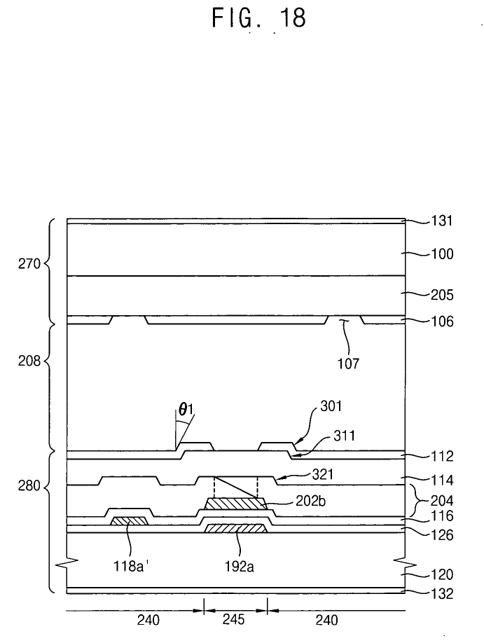

FIG. 18 is a cross-sectional view showing an LCD device in accordance with another embodiment of the present invention. The LCD device of FIG. 18 is the same as the device in FIG. 17 except for a black matrix and a protruding portion. Thus, the same reference numerals will be used to refer to the same or like parts as those described in FIG. 17, and any redundant explanation concerning these parts will be omitted.

Referring to FIG. 18, the LCD device includes the first member 270, the second member 280 and the liquid crystal layer 108.

The first member 270 includes an upper polarizer 131, an upper substrate 100, an overcoating layer 205, a common electrode 106 and a spacer (not shown).

The second member 280 includes a lower polarizer 132, a lower substrate 120, a thin film transistor (TFT) 119, a data line 118a′, a gate line 118b′, a storage capacitor line 192, a gate insulating layer 126, a passivation layer 116, a black matrix 202b, a color filter 204, an organic layer 114 and a pixel electrode 112. Alternatively, the second member 280 may further include a plurality of thin film transistors, a plurality of data lines, a plurality of gate lines, a plurality of storage capacitor lines and a plurality of pixel electrodes. The liquid crystal layer 108 is interposed between the first and second members 270 and 280. The second member 280 includes a plurality of pixel regions 240 and a light blocking region 245. Each of the pixel regions 240 has a substantially V-shape. The light blocking region 245 surrounds the pixel regions 240.

The overcoating layer 205 is on the upper substrate 100. Alternatively, the overcoating layer 205 may be omitted.

The common electrode 106 is formed on the overcoating layer 205. The common electrode 106 has an opening 107 in each of the pixel regions 140.

The gate line 118b′ and the TFT 119 are on the lower substrate 120.

The gate insulating layer 126 is formed on the lower substrate 120 having the gate line 118b′, the storage capacitor line 192 and a gate electrode 118b so that the gate line 118b′, the storage capacitor line 192 and the gate electrode 118b is electrically insulated from the data line 118a′, a source electrode 118a, a drain electrode 118c and a semiconductor layer pattern 118d.

The data line 118a′ is on the gate insulating layer 118b′. The storage capacitor line 192 is underneath the gate insulating layer 126.

The passivation layer 116 is on the lower substrate 120 having the TFT 119, the data line 118a′ and the storage capacitor line 192.

The black matrix 202b is on the passivation layer 116 above the storage capacitor extension part 192a to block the light between the adjacent pixel electrodes 112. A side surface of the black matrix 202b forms a predetermined angle with respect to a direction substantially perpendicular to a surface of the lower substrate 120.

The color filter 204 is on the passivation layer 116 having the black matrix 202b to transmit the light having a predetermined wavelength. The color filter 204 is formed along the side surface of the black matrix 202b to have a third protruding portion 321.

The organic layer 114 is on the lower substrate 120 having the TFT 119, the passivation layer 116 and the color filter 204. The organic layer 114 is formed along the third protruding portion 321 of the color filter 204 to have a second protruding portion 311.

The passivation and organic layers 116 and 114 and the color filter 204 include a contact hole 118c′ through which the drain electrode 118c is partially exposed.

The pixel electrode 112 is formed on the organic layer 114 in each of the pixel regions 140 and in the contact hole 118c′ to be electrically connected to the drain electrode 118c. The pixel electrode 112 is formed along the second protruding portion 311 of the organic layer 114 to form a first protruding portion 301. A side surface of the first protruding portion 301 forms a first angle θ1 with respect to a line that is substantially normal to an upper surface the second member 280. For example, the first angle θ1 may be about 45°. When the first angle θ1 is about 45°, the side surface of the protruding portion 301 is inclined with respect to an upper surface of the lower substrate 120 at an angle of about 45°. Alternatively, the side surface of the protruding portion 301 may be inclined with respect to the upper surface of the lower substrate 120 at various angles.

According to the LCD device shown in FIG. 18, liquid crystals in the liquid crystal layer 208 that is adjacent to the first protruded portion 301 are inclined along the side surface of the first protruding portion 301 to form a plurality of domains in the liquid crystal layer 108, thereby increasing a viewing angle.

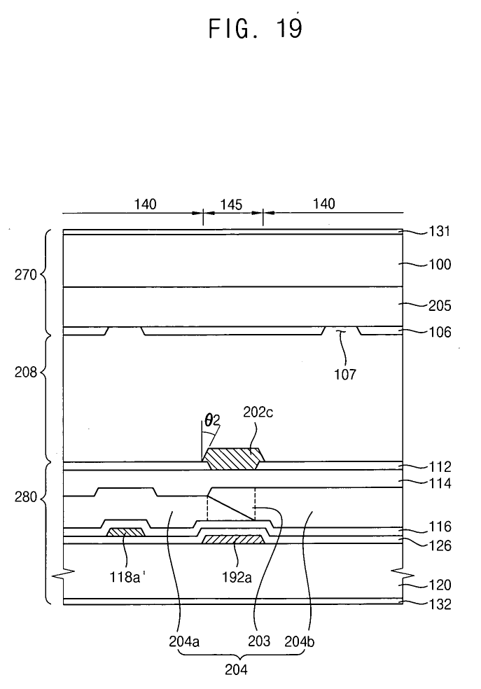

FIG. 19 is a cross-sectional view showing an LCD device in accordance with another embodiment of the present invention. The LCD device of FIG. 19 is the same as the device in FIG. 18 except for a black matrix. Thus, the same reference numerals will be used to refer to the same or like parts as those described in FIG. 18, and any redundant explanation concerning these parts will be omitted.

Referring to FIG. 19, a passivation layer 116 is on a lower substrate 120 having a TFT 119, a data line 118a′ and a storage capacitor line 192.

A color filter 204 is on the passivation layer 116 to transmit light having a predetermined wavelength.

An organic layer 114 is on the lower substrate 120 having the color filter 204.

The passivation and organic layers 116 and 114 and the color filter 204 include a contact hole 118c′ through which a drain electrode 118c is partially exposed.

A pixel electrode 112 is formed on the organic layer 114 in each of pixel regions 240 and in the contact hole 118c′ to be electrically connected to a drain electrode 118c.

A black matrix 202c is on the organic layer 114 and the pixel electrode 112 corresponding to the storage capacitor extension part 192a to block the light between adjacent pixel regions 140. The black matrix 202c protrudes from the pixel electrode 112. A side surface of the black matrix 202c forms a second angle θ2 with respect to a line that is substantially normal to an upper surface of the pixel electrode 112. For example, the second angle θ2 may be about 45°. When the second angle θ2 is about 45°, the side surface of the black matrix 202c is inclined with respect to an upper surface of the lower substrate 120 at an angle of about 45°. Alternatively, the side surface of the black matrix 202c may be inclined with respect to the upper surface of the lower substrate 120 at various angles.

According to the LCD device shown in FIG. 19, a portion of liquid crystals of the liquid crystal layer 108 adjacent to the black matrix 202c is inclined along the side surface of the black matrix 202c to form a plurality of domains in the liquid crystal layer 108, thereby increasing a viewing angle.

Table 1 represents a relationship between the width of a black matrix, the opening ratio and the light transmittance of the LCD device shown in FIGS. 1 to 5.

| Width (μm) | Opening Ratio (%) | Light Transmittance (%) |
|---|---|---|
| 0 | 46 | 3.8 |
| 16 | 53.6 | 4.24 |
| 18 | 52 | 4.12 |
| 20 | 49.8 | 3.94 |

The widths of the black matrixes are about 16 μm, about 18 μm and about 20 μm, respectively. One of the LCD devices does not include the black matrix.

When the width of the black matrix is about 16 μm, the opening ratio and the light transmittance of each of pixels of the LCD device are about 53.6% and about 4.24%, respectively. When the width of the black matrix is about 18 μm, the opening ratio and the light transmittance of each of pixels of the LCD device are about 52% and about 4.12%, respectively. When the width of the black matrix is about 20 μm, the opening ratio and the light transmittance of each of pixels of the LCD device are about 49.8% and about 3.94%, respectively.

When the LCD device includes the black matrix, the opening ratio and the light transmittance are increased. In particular, when the LCD device includes the black matrix having a width of about 16 μm or about 18 μm, the light transmittance is increased by about 11.6% and about 8.4% with respect to the LCD device without the black matrix.

When the LCD device does not include the black matrix, the opening ratio and the light transmittance of the LCD device are about 46% and about 3.8%, respectively. In addition, the width of a color filter overlapping portion of the LCD device having the black matrix is smaller than that of the LCD device without the black matrix.

Therefore, when the LCD device includes a black matrix, the width of the color filter overlapping portion is decreased.

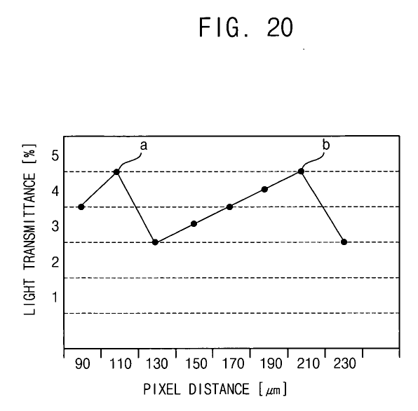

FIG. 20 is a graph showing a relationship between a pixel distance and a light transmittance of the LCD device shown in FIGS. 1 to 5. FIG. 21 is a plan view showing a pixel electrode and an opening pattern corresponding to a point ‘a’ shown in FIG. 20.

Referring to FIGS. 1, 2, 20 and 21, the LCD device includes a plurality of pixels. The pixels are spaced apart from each other by a first pixel distance dₚ₁ in a second polarizing direction. The first pixel distance dₚ₁ equals the width of each of pixel regions 140 and the width of a light blocking region 145. A plurality of domains are formed between an opening 107 of a common electrode 106 and a pixel electrode 112 to increase the viewing angle.

The light transmittance of the LCD device increases as the first pixel distance dₚ₁ increases. However, when the first pixel distance dₚ₁ is too large, the viewing angle of the LCD device is decreased.

In an exemplary embodiment, the light transmittance is optimized when each of the pixels includes one opening 107 and the first pixel distance dₚ₁ is about 110 μm.

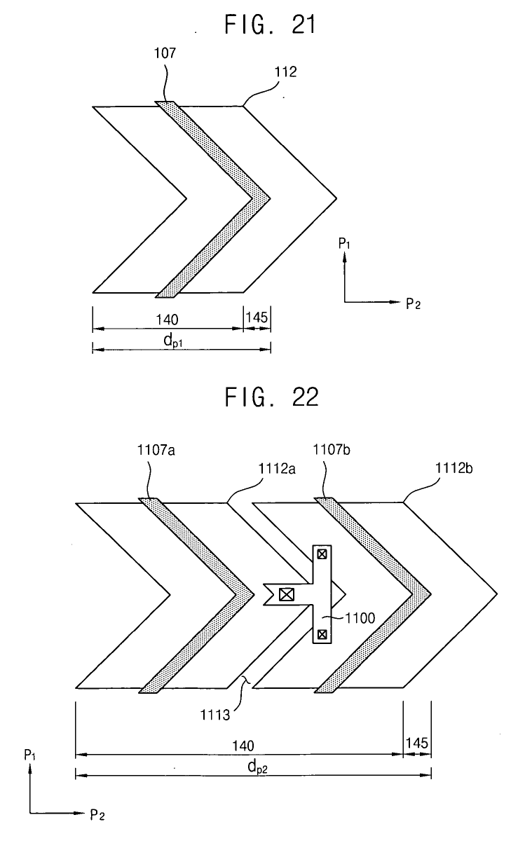

FIG. 22 is a plan view showing a pixel electrode and an opening pattern corresponding to a point ‘b’ shown in FIG. 20. The pixels are spaced apart from each other by a second pixel distance dₚ₂ in a second polarizing direction. When the pixel distance is more than about 120 μm, an auxiliary opening pattern 1113 is formed in the pixel electrode so that the number of the opening patterns is two.

Referring to FIGS. 1, 2, 20 and 22, the pixel electrode includes a first pixel electrode portion 1112a, a second pixel electrode portion 1112, the auxiliary opening pattern 1113 and a coupling capacitor 1100. Each of the first and second pixel electrode portions 1112a and 1112b has a substantially V-shape. The first pixel electrode portion 1112a is substantially parallel to the second pixel electrode portion 1112b. The auxiliary opening pattern 1113 is between the first and second pixel electrode portions 1112a and 1112b. The first pixel electrode portion 1112a is electrically connected to the second pixel electrode portion 1112b through the coupling capacitor 1100.

A common electrode of the LCD device includes a first opening pattern 1107a and a second opening pattern 1107b. The first opening pattern 1107a is substantially parallel to the second opening pattern 1107b.

The light transmittance of the LCD device increases as the second pixel distance dₚ₂ increases. However, when the second pixel distance dₚ₂ is too large, the viewing angle is decreased.

In an exemplary embodiment, the light transmittance is optimized when each of the pixels includes the first and second opening patterns 1107a and 1107b and the second pixel distance dₚ₂ is about 210 μm.

According to the present invention, the pixel electrode and the opening pattern *of the common electrode have the substantially V-shape that increases the response speed of the liquid crystals and the viewing angle. In addition, the black matrix and the color filter overlapping portion block the light between the adjacent pixel electrodes to increase the opening ratio. Furthermore, the overcoating layer may be omitted to simplify the manufacturing process of the substrate for the display device, thereby decreasing the manufacturing cost of the display device.

In addition, the substrate for the display device partially protrudes toward the liquid crystal layer so that some of the liquid crystals are inclined along the protrusion of the substrate, thereby forming domains in the liquid crystal layer. The domains increase the viewing angle of the LCD device.

This invention has been described with reference to the exemplary embodiments. It is evident, however, that many alternative modifications and variations will be apparent to those having skill in the art in light of the foregoing description. Accordingly, the present invention embraces all such alternative modifications and variations as fall within the spirit and scope of the appended claims.

What is claimed is:

1. A member for a display device comprising:
a transparent substrate including a pixel region having a substantially V-shape and a light blocking region surrounding the pixel region;
a black matrix in the light blocking region;
a color filter including:
a plurality of color filter portions, each of the color filter portions being in the pixel region; and
a color filter overlapping portion between adjacent color filter portions; and
a transparent electrode on the color filter, the transparent electrode including an opening that is patterned to extend substantially parallel to a side of the pixel region.

2. The member of claim 1, wherein the black matrix is formed on a portion of the light blocking region.

3. The member of claim 2, wherein the black matrix is between adjacent pixel regions.

4. The member of claim 1, wherein the transparent electrode is a common electrode receiving a common voltage that is applied to the pixel region and its neighboring pixel regions.

5. The member of claim 1, wherein the color filter overlapping portion comprises at least two materials that are substantially the same material as at least two of the color filter portions.

6. The member of claim 1, wherein the opening is patterned to have a substantially Y-shape.

7. The member of claim 1, wherein the transparent electrode comprises a pixel electrode having a substantially V-shape corresponding to the pixel region.

8. The member of claim 7, wherein the color filter is on the transparent substrate having the black matrix.

9. The member of claim 8, wherein the black matrix comprises an inclined surface, and the color filter is formed on an upper surface of the transparent substrate along the inclined surface.

10. The member of claim 9, wherein the inclined surface forms an angle of about 45° with respect to the upper surface of the transparent substrate.

11. The member of claim 7, wherein the black matrix is on the color filter and the transparent electrode.

12. The member of claim 11, further comprising an organic layer between the color filter and the transparent electrode and having a substantially flat surface, and the black matrix comprises an inclined surface that forms an angle of about 45° with respect to an upper surface of the transparent substrate.

13. A method of manufacturing a display device comprising:
forming a black matrix in a light blocking region of a transparent substrate, the transparent substrate including a pixel region having a substantially V-shape and the light blocking region surrounding the pixel region;
forming a plurality of color filter portions in the pixel region and a color filter overlapping portion in the light blocking region;
depositing a transparent conductive layer on the color filter portions and the color filter overlapping portion; and
partially etching the transparent conductive layer to form an opening that extends substantially parallel to a side of the pixel region.

14. The method of claim 13, wherein the black matrix is formed on a portion of the light blocking region.

15. The method of claim 13, wherein the color filter portions and the color filter overlapping portion are formed on the transparent substrate having the black matrix.

16. The method of claim 13, wherein the black matrix is formed on the transparent conductive layer having the opening.

17. A liquid crystal display device comprising:
a first member including:
an upper substrate including a pixel region having a substantially V-shape and a light blocking region surrounding the pixel region;
a black matrix in the light blocking region;
a color filter including:
a plurality of color filter portions, each of the color filter portions being in the pixel region; and
a color filter overlapping portion between adjacent color filter portions; and
a transparent electrode on the color filter, the transparent electrode including an opening that extends substantially parallel to a side of the pixel region;
a second member including:
a lower substrate positioned substantially parallel to the upper substrate;
a switching element on the lower substrate; and
a pixel electrode corresponding to the pixel region, the pixel electrode being electrically connected to an electrode of the switching element; and
a liquid crystal layer interposed between the first and second members.

18. The liquid crystal display device of claim 17, wherein the black matrix is on a portion of the light blocking region.

19. The liquid crystal display device of claim 17, further comprising a storage capacitor line on the lower substrate, wherein the storage capacitor line partially overlaps the pixel electrode.

20. The liquid crystal display device of claim 19, further comprising a storage capacitor extension part formed in an area between adjacent pixel electrodes, wherein the storage capacitor extension part is electrically connected to the storage capacitor line.

21. The liquid crystal display device of claim 20, wherein a width of the storage capacitor extension part is greater than an interval between the adjacent pixel electrodes.

22. The liquid crystal display device of claim 17, wherein the first and second members further comprise an upper polarizer on the upper substrate and a lower polarizer on the lower substrate, wherein the upper and lower polarizers have a first polarizing direction and a second polarizing direction, respectively.

23. The liquid crystal display device of claim 22, wherein the first polarizing direction is about 0° with respect to a display surface of the liquid crystal display device, and the polarizing direction is about 90 with respect to the display surface of the liquid crystal display device.

24. The liquid crystal display device of claim 23, wherein a side of the pixel region forms an angle of about 45° with respect to the first polarizing direction and the second polarizing direction.

25. The liquid crystal display device of claim 17, wherein the pixel electrode comprises:
a plurality of pixel electrode portions;
an auxiliary opening between the pixel electrode portions; and
a coupling capacitor through which the pixel electrode portions are electrically connected.

26. The liquid crystal display device of claim 25, wherein the common electrode further comprises a plurality of openings.
